(19) United States
(12) Patent Application Publication
(10) Pub. No.: US 2002/0180507 A1
(43) Pub. Date: Dec. 5, 2002

(54) Resistor network

(75) Inventors: Chia-Hsing Yu, Taipei (TW); Ta-Hsiu Huang, Taipei (TW)

Correspondence Address: VOLPE AND KOENIG, P.C., SUITE 400, ONE PENN CENTER, 1617 JOHN F. KENNEDY BOULEVARD, PHILADELPHIA, PA, 19103, US

(73) Assignee: VIA Technologies, Inc., Taipei (TW)

(21) Appl. No.: 10/135,221

(22) Filed: Apr. 30, 2002

(30) Foreign Application Priority Data
May 31, 2001 (TW) 90113243

(51) Int. Cl. H03L 5/00

(52) U.S. Cl. 327/308

(57) ABSTRACT

A resistor network which utilizes modulating signals to modulate the resistance value of the individual resistive elements thereof. The resistor network includes a plurality of input terminals and output terminals, and a resistive element and a first switch connected in series with the resistive element is provided between each of the input terminals and output terminals. Each resistive elements includes a plurality of resistors connected in parallel, and a plurality of second switches each of which is connected with a corresponding one of the resistors. An equivalent resistance value of the resistive element is obtained between the input terminal and the output terminal by controlling the on/off states of the second switches through the modulating signals to determine which resistors can be selectively connected with the input terminal and the output terminal.

### FIELD OF THE INVENTION

The present invention relates to a resistor network, and more particularly, the present invention relates o a resistor network which makes use of modulating signals to dynamically modulate the resistance value of the individual resistive elements in the resistor network.

### BACKGROUND OF THE INVENTION

With the advent of advanced semiconductor manufacturing technique and computer technology, the integrated circuit techniques have been widely employed in a variety of electronic products in the areas of digital image processing, telecommunications and computer networks. There is a continuing demand for the electronic products that are easier to use and more accessible to a greater number of users.

In general, the fundamental building blocks of an integrated circuit are electrical and electronic elements. These elements may include transistors, resistors and capacitors. An integrated circuit may comprise a great number of electrical and electronic components, and the performance of these electrical and electronic components are substantially a decisive factor for the functionality and reliability of an integrated circuit.

For example, the basic element used in an integrated circuit device is a resistor. Please refer to FIG. 1, which illustrates a circuit configuration diagram of a prior resistor network for use in an integrated circuit. The prior resistor network 10 includes a plurality of resistors r₁,r₂,r₃, . . . ,rₘ. Each of the resistors r₁,r₂,r₃, . . . ,rₘ is provided with a first terminal and a second terminal. The first terminals In₁,In₂,In₃, . . . ,Inₘ of the resistors r₁,r₂,r₃, . . . ,rₘ act as the input terminals for an input voltage signal Vᵢₙ (certainly, each of the first terminals may be applied to receive individual input voltage signals), and each of the second terminals N₁,N₂,N₃, . . . ,Nₘ is respectively connected in series with a corresponding one of m switches S₁,S₂,S₃, . . . ,Sₘ. The resistor network further provides an enable signal input terminal for receiving an external enable signal to drive the switches S₁,S₂,S₃, . . . ,Sₘ to turn on or off. If the enable signal enables all the switches S₁,S₂,S₃, . . . ,Sₘ to turn on, the input voltage signal Vᵢₙ will be inputted from the input terminal In₁,In₂,In₃, . . . ,Inₘ and passed through the individual switches S₁,S₂,S₃, . . . ,Sₘ and finally outputted through the output terminals OUT₁, OUT₂, OUT₃, . . . ,OUTₘ. If the enable signal disables all the switches S₁,S₂,S₃, . . . ,Sₘ to turn off, the input voltage signal Vᵢₙ can not be outputted through the output terminals OUT₁, OUT₂, OUT₃, . . . ,OUTₘ, resulting in an open-circuit.

Nonetheless, the resistance value of each of resistors r₁,r₂,r₃, . . . ,rₘ is unchangeable. In relation to the electronic products involved with some special technical fields, however, there is a frequent need to design the resistance value of the individual resistors so that they may be dynamically modulated, such that the resistance value of the resistor can be modulated to optimize the matching effect among the resistors and other electronic circuits.

It is highly desirable to provide a resistor network which utilizes modulating signals to modulate the resistance value of the individual resistors in the resistor network, in such a way that the resistance value of the individual resistors of the resistor network can be dynamically modulated in accordance with the requirements of the circuit layout.

### SUMMARY OF THE INVENTION

An object of the present invention is the provision of a resistor network that includes a plurality of resistive elements, and the resistance value of the individual resistive elements can be modulated according to the modulating signals applied thereto so as to obtain an equivalent resistance value.

Another object of the present invention is the provision of a resistor network including a modulating signal generator for generating a plurality of modulating signals in response to a plurality of control signals, and a plurality of resistive elements each of which is provided with an input terminal and an output terminal, wherein an equivalent resistance value is obtained between the input terminal and the output terminal according to the modulating signals.

Another object of the present invention is the provision of a resistor network, wherein the resistance value of each of the resistors of the resistor network can be modulated in response to modulating signals, and thereby serving as an active circuit element.

It is still an object of the present invention to provide a resistor network including a modulating signal generator for generating a plurality of modulating signals in response to a plurality of control signals, a plurality of resistive elements, each of which includes an input terminal and an output terminal, and a plurality of first switches, each of which is connected in series with one of the resistive elements. An equivalent resistance value is obtained between the input terminal and the output terminal according to the modulating signals. Each of the resistive elements further includes a plurality of resistors and a plurality of second switches connected in series with one of the resistors. Each of the second switches are used to selectively connect the resistors with the input terminal and the output terminal to form an equivalent resistor between the input terminal and the output terminal.

The foregoing and other features and advantages of the present invention will be more apparent through the following descriptions with reference to the accompanying drawings, in which:

### BRIEF DESCRIPTION OF THE DRAWINGS

FIG. 1 is a circuit configuration diagram of a prior resistor network;

FIG. 2 is a circuit configuration diagram of a resistor network in accordance with the present invention;

FIG. 3 is a circuit configuration diagram of an active resistive element of the resistor network in accordance with the present invention; and

FIG. 4 illustrates a circuit symbolic view of the individual first switch or the individual second switch of the resistor network according to a first preferred embodiment of the present invention.

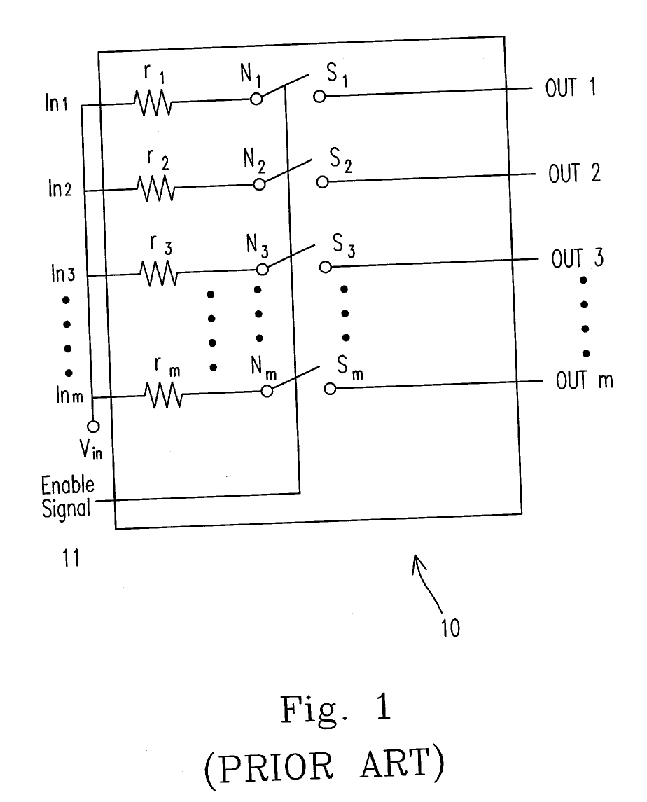

### DETAILED DESCRIPTION OF THE PREFERRED EMBODIMENT

The resistor network embodying the present invention will be described in detail with reference to the following preferred embodiment. It is to be noted that the following descriptions of the preferred embodiment of the present invention, presented herein, are for the purpose of illustration and description only. It is not intended to be exhaustive and the invention is not to be limited to the precise form disclosed.

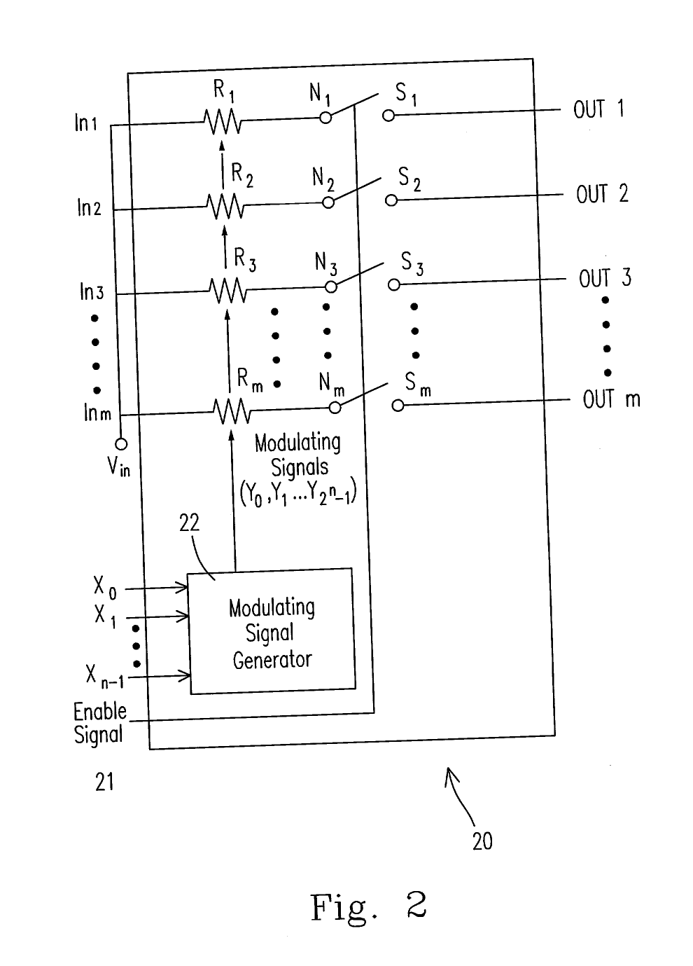

The resistor network of the present invention basically utilizes a plurality of modulating signals for dynamically modulating the resistance value of the individual resistive elements in the resistor network. This is in order to provide the resistor network with the functionality of resistance value modulation. Turning now to FIG. 2, a first preferred embodiment of the resistor network 20 according to the present invention comprises a plurality of resistive elements R₁,R₂,R₃, . . . ,Rₘ, each of which is coupled in series with a corresponding one of the first switch elements S₁,S₂,S₃, . . . ,Sₘ. Each of the resistive elements R₁,R₂,R₃, . . . ,Rₘ is provided with a first terminal and a second terminal, in which each of the first terminals In₁,In₂,In₃, . . . ,Inₘ is connected to an input voltage signal Vᵢₙ to serve as an input terminal for the input voltage signal Vᵢₙ (certainly, each of the first input terminals may be applied to receive individual input voltage signals), and each of the second terminals N₁,N₂,N₃, . . . ,Nₘ is respectively connected to a corresponding one of the first switches. The enable signal input terminal is used to receive an external enable signal as the driving signals for controlling the on/off states of each of the first switches S₁, S₂, S₃, . . . ,Sₘ.

In order to allow the resistive elements R₁,R₂,R₃, . . . ,Rₘ to be provided with the functionality of resistance value modulation, a modulating signal generator 22 is further provided for providing modulating signals Y₀,Y₁, . . . ,Y₂ⁿ₋₁ to each of the resistive elements R₁,R₂,R₃, . . . ,Rₘ to modulate the resistance value of each of the resistive elements R₁,R₂,R₃, . . . ,Rₘ. In this preferred embodiment, the modulating signal generator 22 is exemplified by a n×2ⁿ decoder which receives n control signals and generates 2ⁿ modulating signals in response to the control signals, however, other digital signal generators that can be used to generate modulating signals for modulating the resistive characteristics of the resistive elements are also encompassed within the scope as to be protected by the present invention.

In FIG. 2, the n×2ⁿ decoder 22 is used to receive n control signals X₀,X₁, . . . ,Xₙ₋₁ and output 2ⁿ modulating signals Y₀,Y₁, . . . ,Y₂ⁿ₋₁ in response to the control signals. Each of the modulating signals Y₀,Y₁, . . . ,Y₂ⁿ₋₁ generated by the decoder 22 is respectively provided to each of the resistive elements R₁,R₂,R₃, . . . ,Rₘ as the modulating signals for modulating the resistance value of each of the resistive elements. Certainly, it is not necessary that all the 2ⁿ modulating signals are provided to each of the resistive elements R₁,R₂,R₃, . . . ,Rₘ, i.e. the 2ⁿ modulating signals can be grouped into an average of m sets of modulating signals to be provided to individual resistive elements, so as to generate different equivalent resistance values of the resistive elements.

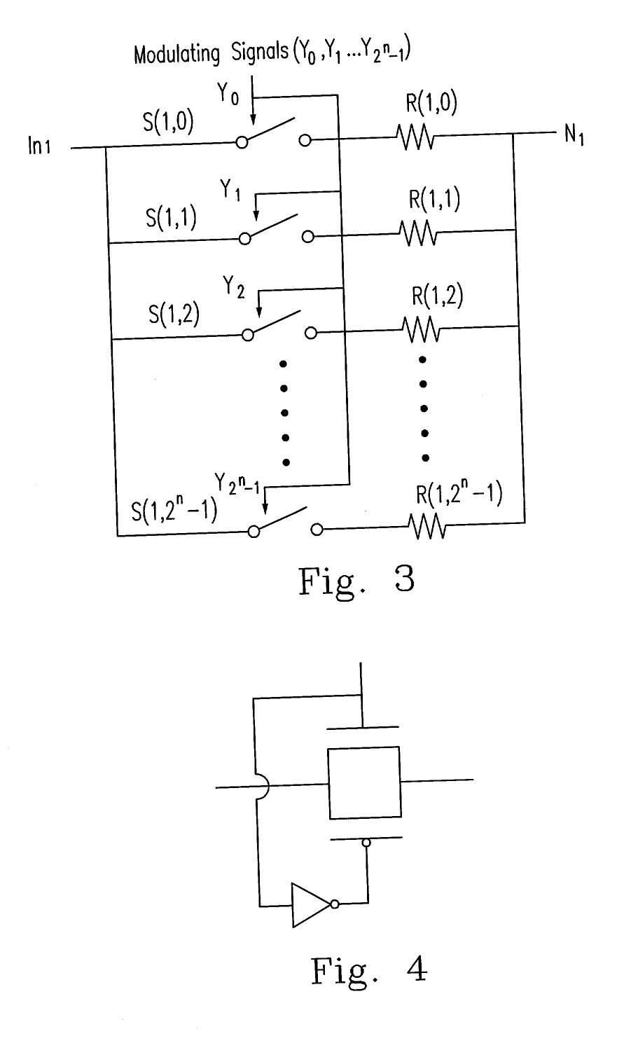

Please refer to FIG. 3 which shows the circuit configuration of the resistive element of the resistor network 20 according to a first preferred embodiment of the present invention. For the purpose of illustration, in this descriptive embodiment the resistive element R₁ will be taken as an example to explain the circuit configuration and resistance value modulation operation of the resistive elements. However, the circuit configuration and the resistance value modulation operation of other resistive elements can be deduced in an analogous way based on the following studies. According to a first preferred embodiment of the present invention, the resistive element R₁ of the resistor network 20 is configured to include a plurality of 2ⁿ resistors R(1,0), R(1,1), . . . , R(1,2ⁿ−1) that are connected in parallel. Each of the resistors R(1,0), R(1,1), . . . , R(1,2ⁿ−1) is connected in series with a corresponding one of 2ⁿ second switches S(1,0), S(1,1), . . . , S(1,2ⁿ−1). The modulating signals (Y₀,Y₁, . . . ,Y₂ⁿ₋₁) generated by the decoder 22 are respectively provided to each of the second switches S(1,0), S(1,1), . . . , S(1,2ⁿ−1) to control their on/off states. In this manner, a modulated resistance value can be obtained between the terminals In₁ and N₁ as the resistance value of the resistive element R₁.

In reference to the manner for modulating the resistance value of the resistive element R₁ of the resistor network 20 according to the present invention, it will be further described by way of the following discussions. In FIG. 3, if all the switch elements are turned on, the resistance value present between the input terminal In₁ and the output terminal N₁ of the resistive element R₁ will be built up by connecting the resistors R(1,0),R(1,1) . . . ,R(1,2ⁿ−1) in parallel, and the resistance value of the resistive element R₁ will result in:

$${R}_{1} = \frac{R ( 1 , 0 ) \times R ( 1 , 1 ) \times … \times R ( 1 , {2}^{n} - 1 )}{R ( 1 , 0 ) + R ( 1 , 1 ) + … + R ( 1 , {2}^{n} - 1 )}$$

If only the second switches S(1,0), S(1,1) are turned on, the resistance value present between the input terminal In₁ and the output terminal N₁ of the resistive element R₁ will be built up by connecting the resistors R(1,0) and R(1,1) in parallel, we obtain:

$${R}_{1} = \frac{R ( 1 , 0 ) \times R ( 1 , 1 )}{R ( 1 , 0 ) + R ( 1 , 1 )}$$

It is apparent from the above statements that the modulating signals generated by the decoder 22 are respectively provided to the second switches S(1,0),S(1,1) . . . ,S(1,2ⁿ−1) to control the on/off states of the individual second switches S(1,0),S(1,1) . . . , S(1,2ⁿ−1), so as to provide a resistance value which is built up by connecting the corresponding resistive elements in parallel for output. The resistance value of the resistive element R₁ is built up by connecting the resistive elements that are selected by the turned-on second switches in parallel. As a result, the resistance value of the resistive element of the resistor network, according to the present invention, is no longer unchangeable. However, it can be modulated according to the modulating signals generated by the modulating signal generator. Therefore a resistor network with resistance value modulation functionality can be obtained.

Furthermore, as can be known by a person having ordinary skill in the art, it is not necessary to provide all the 2ⁿ modulating signals to each of the resistive elements R₁,R₂,R₃, . . . ,Rₘ, that is, the 2ⁿ modulating signals can be grouped into an average of m sets of modulating signals to be provided to individual resistive elements, so that each of the second switches receives different modulating signals. It can be known that different resistors are permitted to connected in parallel, and different resistance values of the resistive element can be obtained accordingly.

FIG. 4 illustrates a circuit symbolic view of the individual first switch or the individual second switch of the resistor network according to the present invention. It can be inferred from FIG. 4 that the individual first switch or the individual second switch is accomplished by a transmission gate circuit. It is to be understood from FIG. 4 that when the input of the transmission gate circuit is high, the transmission gate circuit will achieve the switch-off function, and when the input of the transmission gate circuit is low, the transmission gate circuit will achieve the switch-on function. As is well known by a person skilled in the art, shifting the location of the inverting gate of the gate transmission circuit also can achieve the switch-off function when the input is low, and achieve the switch-on function when the input is high.

In sum, the present invention provides a resistor network, in which the resistance value of each of the resistive elements is modulated according to the modulating signals applied thereto. The resistive elements of the resistor network of the present invention include a plurality of resistors connected in parallel and a plurality of second switches connected in series with a corresponding one of the resistors. The on/off states of the second switches are in the control of the modulating signals, and the number of the resistors that can be used to form an equivalent resistor can be determined by the modulating signals so as to obtain different equivalent resistance values. The resistor network of the present invention provides a modulating signal generator, such as a decoder, for generating a plurality of modulating signals. The modulating signals are provided to control the on/off states of the second switches. The second switches are used to selectively connect the resistor in parallel to form an equivalent resistor according to their on/off states. The resistance value for the resistive element of the resistor network of the present invention is exactly the resistance value of the equivalent resistor that is formed by connecting the selected resistors in parallel. The aforementioned circuit configuration of the resistor network according to the present invention makes the resistor network as an active circuit element, and it can be satisfied with the applications in the related technical field that variable resistors are needed as the basic elements of the circuit.

Although the present invention has been described and illustrated in detail, it is to be clearly understood that the same is by the way of illustration and example only and is not to be taken by way of limitation, the spirit and scope of the present invention being limited only by the terms of the appended claims.

What is claimed is:

1. A resistor network comprising:
a modulating signal generator which provides a plurality of modulating signals in response to a plurality of control signals; and
a plurality of resistive elements each of which is provided with an input terminal and an output terminal, wherein an equivalent resistance value is obtained between said input terminal and said output terminal of each of said resistive elements according to said modulating signals.

2. The resistor network according to claim 1 further comprising a plurality of first switches, each of which is connected in series with one of said resistive elements to selectively connect each of said resistive elements with said input terminal and said output terminal.

3. The resistor network according to claim 2 further comprising an enable signal to enable each of said first switches to selectively connect each of said resistive elements with said input terminal and said output terminal.

4. The resistor network according to claim 2 wherein each of said first switches comprises a transmission gate circuit.

5. The resistor network according to claim 1 wherein each of said resistive elements further comprising:
a plurality of resistors connected in parallel; and
a plurality of second switches, each of which is connected in series with one of said resistors for selectively connecting each of said resistors with said input terminal and said output terminal.

6. The resistor network according to claim 5 wherein each of said second switches comprises a transmission gate circuit.

7. The resistor network according to claim 1 wherein said modulating signal generator comprises a decoder.

8. A resistor network comprising:
a modulating signal generator which provides a plurality of modulating signals in response to a plurality of control signals; and
a plurality of resistive elements each of which is provided with an input terminal and an output terminal, wherein an equivalent resistance value is obtained between said input terminal and said output terminal of each of said resistive elements according to said modulating signals;
wherein each of said resistive elements further includes a plurality of resistors connected in parallel, and a plurality of second switches each of which is connected in series with one of said resistors for selectively connecting each of said resistors with said input terminal and said output terminal.

9. The resistor network according to claim 8 wherein each of said second switches is a transmission gate circuit.

10. The resistor network according to claim 8 further comprising a plurality of first switches, each of which is connected in series with one of said resistive elements to selectively connect each of said resistive elements with said input terminal and said output terminal.

11. The resistor network according to claim 10 further comprising an enable signal to enable each of said first switches to selectively connect each of said resistive elements with said input terminal and said output terminal.

12. The resistor network according to claim 10 wherein each of said first switches comprises a transmission gate circuit.

13. The resistor network according to claim 8 wherein said modulating signal generator comprises a decoder.
